(19) United States
(12) Patent Application Publication
(10) Pub. No.: US 2012/0154042 A1
(43) Pub. Date: Jun. 21, 2012

(54) ANALOG MULTIPLIER

(75) Inventors: Praveen Varma Nadimpalli, Chandler, AZ (US); Joseph Hubert Colles, Bonsall, CA (US)

(73) Assignee: RF MICRO DEVICES, INC., Greensboro, NC (US)

(21) Appl. No.: 13/047,361

(22) Filed: Mar. 14, 2011

Related U.S. Application Data
(60) Provisional application No. 61/424,913, filed on Dec. 20, 2010.

(51) Int. Cl. H03F 1/00; G06G 7/16

(52) U.S. Cl. 330/199; 327/356

(57) ABSTRACT

An exemplary embodiment of an analog multiplier may include a voltage controlled resistance circuit, a first transistor and a second transistor, where the resistance of the voltage controlled resistance circuit is based upon a difference between a supply voltage and a first input voltage and a constant current supply. The current passing through the voltage controlled resistance circuit is based upon a difference between the voltage supply and a second input voltage. The first transistor may be configured to mirror the current passing through the voltage controlled resistance circuit.

### RELATED APPLICATIONS

This application claims the benefit of U.S. provisional patent application No. 61/424,913, entitled “Analog Multiplier,” filed on Dec. 20, 2010, the disclosure of which is incorporated herein by reference in its entirety. This application is related to a concurrently filed U.S. non-provisional patent application Ser. No. ______, entitled “Analog Multiplier,” filed on ______, the disclosure of which is incorporated herein by reference in its entirety.

### FIELD OF THE DISCLOSURE

Embodiments described herein relate to an analog multiplier circuit. In addition, the embodiments described herein are further related to use of an analog multiplier to generate one or more controlled currents based upon a first input voltage and a second input voltage.

### BACKGROUND

Analog multipliers may be used to multiply two analog signals to produce an output, which is effectively the product of the analog signals. In some cases, an analog multiplier may be used to multiply a first analog signal by the inverse of a second analog signal. The output of an analog multiplier may be either a voltage or a current.

Some analog multipliers may use two diodes to generate a current, which is an exponential function of the two input voltages. As a result, any offset voltage from the two input voltages may be exponentially magnified. In addition, the exponential function of the diodes tends to be sensitive to both process variations and temperature variations. As a result, the output of an analog multiplier may vary with process.

These process variations may affect the accuracy of the analog multiplier and lead to poor manufacturing yields or result in the need for post manufacturing calibration. Accordingly, there is a need for a new analog multiplier circuit or technique that substantially reduces or eliminates the process and batch to batch variations in an output of an analog multiplier.

### SUMMARY

The embodiments described in the detailed description relate to process independent analog multipliers used to generate a process independent controlled current source. A first field effect transistor and a second field effect transistor are controlled to operate in a triode region of operation. A first fixed resistor may be coupled to the drain of the first field effect transistor. A first operational amplifier is configured to receive a first reference voltage, where the operational amplifier regulates the voltage across the first fixed resistor and the drain-to-source resistance of the first field effect transistor to be substantially equal to the supply voltage less the first voltage. A constant current source coupled to the first resistor provides a reference current to pass through the first resistor and drain-to-source resistance of the first field effect transistor.

A second field effect transistor is also controlled to operate in the triode region of operation and to have substantially the same drain-to-source impedance as the first field effect transistor. A control node of the second field effect transistor is coupled to a control node of the first field effect transistor. The resistance of the first resistor may equal the resistance of the second resistor. A second resistor may be coupled to the drain of the second field effect transistor. As a result, the combined resistance of the second resistor and the drain-to-source resistance of the second field effect transistor may be substantially equal to the combined resistance of the drain-to-source resistance of the first field effect transistor and the resistance of the first resistor.

A second operational amplifier may be configured to regulate a second control voltage and may be placed across the combined resistance of the second resistor and the drain-to-source resistance of the second field effect transistor. As a result, the drain current of the second field effect transistor is substantially equal to the reference current multiplied by a ratio of the supply voltage less the second voltage divided by the supply voltage less the first voltage. A current mirror coupled to the output of the second operational amplifier provides an output current substantially equal to the drain current of the second field effect transistor.

A first exemplary embodiment of an analog multiplier includes a voltage controlled resistance circuit, a first operational amplifier, and a first transistor. The voltage controlled resistance circuit may include a first node, a second node coupled to a supply voltage, and a control node coupled to a first input voltage. The voltage controlled resistance circuit may further include a reference current source configured to provide a reference current. The impedance between the first node and second node of the voltage controlled resistance circuit may be based upon a ratio of the supply voltage less the first input voltage divided by the reference current. The first operational amplifier may include an inverted input coupled to a second input voltage, a non-inverted input coupled to the first node of the voltage controlled resistance circuit, and an output node. The first transistor may include a gate in communication with the output node of the first operational amplifier, a source coupled to a reference voltage, and a drain coupled to the non-inverted input of the first operational amplifier and the first node of the voltage controlled resistance circuit.

Another exemplary embodiment of an analog multiplier may be a method including generating a reference current, wherein the reference current passes through a first element. A first voltage generated across the first element is controlled to set a resistance of the first element based upon a first input voltage. A resistance of a second element is controlled to be substantially equal to the resistance of the first element. A second voltage generated across the second element is controlled based upon a second input voltage to generate a current passing through a third element.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure, and together with the description serve to explain the principles of the disclosure.

FIG. 1 depicts an exemplary embodiment of an analog multiplier referenced to a constant current source.

FIG. 2 depicts a second exemplary embodiment of an analog multiplier referenced to a constant current source.

FIG. 3 depicts a third exemplary embodiment of an analog multiplier referenced to a constant current source.

FIG. 4 depicts an exemplary application of the analog multiplier of FIGS. 1-2 to control the operation of a radio frequency power amplifier.

FIG. 5 depicts an exemplary relationship between a controlled current output and a first input voltage and a second input voltage.

FIG. 6 depicts an exemplary application of the analog multipliers of FIGS. 1-3 to generate either a proportional to absolute temperature current source or an inversely proportional to absolute temperature current source referenced to a constant current source.

### DETAILED DESCRIPTION

The embodiments set forth below represent the necessary information to enable those skilled in the art to practice the disclosure and illustrate the best mode of practicing the disclosure. Upon reading the following description in light of the accompanying drawings, those skilled in the art will understand the concepts of the disclosure and will recognize applications of these concepts not particularly addressed herein. It should be understood that these concepts and applications fall within the scope of the disclosure and the accompanying claims.

The embodiments described herein relate to process independent analog multipliers used to generate a process independent controlled current source. A first field effect transistor and a second field effect transistor are controlled to operate in a triode region of operation. A first fixed resistor may be coupled to the drain of the first field effect transistor. A first operational amplifier is configured to receive a first reference voltage, where the operational amplifier regulates the voltage across the first fixed resistor and the drain-to-source resistance of the first field effect transistor to be substantially equal to the supply voltage less the first voltage. A constant current source coupled to the first resistor provides a reference current to pass through the first resistor and drain-to-source resistance of the first field effect transistor.

A second field effect transistor is also controlled to operate in the triode region of operation and to have substantially the same drain-to-source impedance as the first field effect transistor. A control node of the second field effect transistor is coupled to a control node of the first field effect transistor. The resistance of the first resistor may equal the resistance of the second resistor. A second resistor may be coupled to the drain of the second field effect transistor. As a result, the combined resistance of the second resistor and the drain-to-source resistance of the second field effect transistor may be substantially equal to the combined resistance of the drain-to-source resistance of the first field effect transistor and the resistance of the first resistor.

A second operational amplifier may be configured to regulate a second control voltage and may be placed across the combined resistance of the second resistor and the drain-to-source resistance of the second field effect transistor. As a result, the drain current of the second field effect transistor is substantially equal to the reference current multiplied by a ratio of the supply voltage less the second voltage divided by the supply voltage less the first voltage. A current mirror coupled to the output of the second operational amplifier provides an output current substantially equal to the drain current of the second field effect transistor.

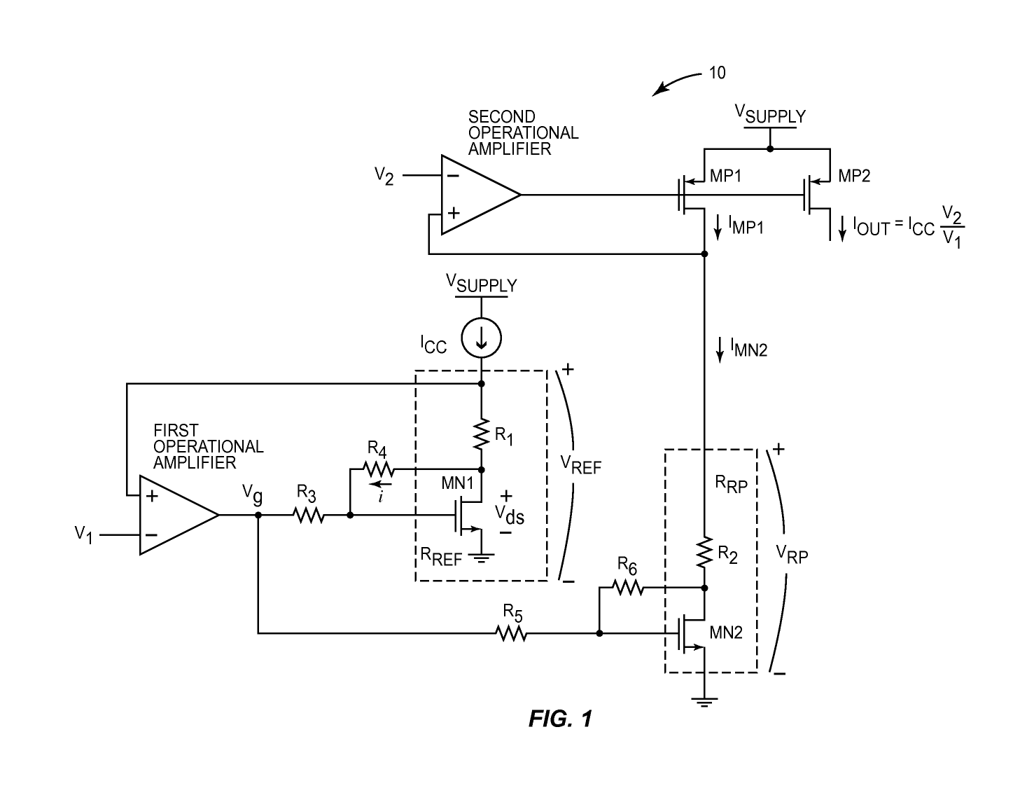

FIG. 1 depicts an exemplary embodiment of an analog multiplier 10, where the output current I_{OUT} is substantially based upon a current of a constant current source I_{CC} and the ratio of a second input voltage V₂ to a first input voltage V₁.

The analog multiplier 10 includes a first controlled resistance R_{REF} and a second controlled resistance R_{RP}. The impedance of the first controlled resistance R_{REF} equals the resistance of a first resistor R₁ plus a drain-to-source resistance R_{MN1} of a first transistor MN1. A source of the first transistor MN1 is coupled to a reference voltage, ground, while the drain of the first transistor is coupled to the first resistor R₁. The resistance of the second controlled resistance R_{RP} equals a resistance of a second resistor R₂ plus a drain-to-source resistance R_{MN2} of a second transistor MN2. A source of the second transistor MN2 is coupled to a reference voltage, ground, while the drain of the second transistor is coupled to the second resistor R₂. The drain-to-source resistance R_{MN1} of the first transistor MN1, operating in a triode mode region of operation, is provided by equation (1).

$${R}_{MN 1} = \frac{1}{{K}_{MN 1} ( {V}_{{gs}_{MN 1}} - {V}_{t} - {V}_{{ds}_{MN 1}} / 2 )} , \qquad ( 1 )$$

where V_{gs}_{_{MN1}} is the gate-to-source voltage of the first transistor MN1, Vₜ is the threshold voltage of the first transistor MN1, V_{ds}_{_{MN1}} is the drain-to-source voltage across the first transistor MN1, and K_{MN1} is a constant. The value of K_{MN1} for a NMOS FET transistor may be calculated as given in equation (2).

$${K}_{MN 1} = {μ}_{n} {C}_{ox} ( \frac{{W}_{MN 1}}{{L}_{MN 1}} ) , \qquad ( 2 )$$

where L_{MN1} is the channel length of the first transistor MN1, W_{MN1} is the channel width of the first transistor MN1, μ_{MN1} is the mobility of an electron in a material of the first transistor MN1, and Cₒₓ is the gate oxide capacitance per unit area of the first transistor MN1.

As indicated by equation (1), the drain-to-source impedance of the first transistor is dependent upon the drain-to-source voltage V_{ds}_{_{MN1}} of the first transistor. The non-linear effects of the drain-to-source voltage V_{ds}_{_{MN1}} on the impedance across the FET transistor may be compensated for by a first linearization circuit composed of a third resistor R₃ and a fourth resistor R₄, for the first transistor MN1; and a second linearization circuit composed of a fifth resistor R₅ and a sixth resistor R₆, for the second transistor MN2.

The third resistor R₃ is coupled between the output of a first operation amplifier OPAMP₁ and the gate of the first transistor MN1. The fourth resistor R₄ is coupled between the gate and drain of the first transistor MN1. The fifth resistor R₅ is coupled between the output of the first operational amplifier OPAMP₁ and the gate of the second transistor MN2. The sixth resistor R₆ is coupled between the gate and drain of the second transistor MN2.

The first operational amplifier OPAMP₁ generates a gate control voltage V_{g} based upon the difference between a first input voltage V₁, applied to the inverting input of the OPAMP₁ and the voltage V_{REF} across the first controlled resistance R_{REF}. The gate-to-source voltage V_{gs}_{_{MN1}} of the first transistor MN1 is given by equation (3), where the gate current is assumed to be zero relative to the current “i” passing through resistors R₃ and R₄.

V_{gs}_{_{MN1}}=V_{g}−iR₃ (3)

The voltage V_{ds}_{_{MN1}} of the first transistor MN1 is given by equation (4).

V_{ds}_{_{MN1}}=V_{g}−i(R₃+R₄) (4)

Setting the resistance of R₃ and R₄ to R, re-arranging variables, and solving for V_{gs}_{_{MN1}} of the first transistor MN1 yields equation (5).

V=(V_{g}−V_{ds}_{_{MN1}})/2 (5),

where V_{g} is a gate control voltage at the output of the operational amplifier OPAMP₁, and V_{ds}_{_{MN1}} is the drain-to-source voltage of the first transistor MN1.

Substituting equation (5) into equation (1) yields a “linearized” equation (6) for the drain-to-source resistance R_{MN1} of the first transistor MN1 that is not dependent upon the drain-to-source voltage V_{ds}_{_{MN1}} of the first transistor MN1.

$${R}_{MN 1} = \frac{1}{{K}_{MN 1} [ {V}_{g} / 2 - {V}_{t} ]} \qquad ( 6 )$$

Assuming that a resistance of the fifth resistor R₅ equals the resistance of the sixth resistor R₆, a similar result is reached for the drain-to-source resistance of the second transistor MN2, which is given by equation (7).

$${R}_{MN 2} = \frac{1}{{K}_{MN 2} [ {V}_{g} / 2 - {V}_{t} ]} \qquad ( 7 )$$

Assuming that the first transistor MN1 and the second transistor MN2 have the same threshold voltage Vₜ, the ratio of the drain-to-source resistance of the first transistor MN1 to the drain-to-source resistance of the second transistor MN2 is shown in equation (8).

$$\frac{{R}_{MN 1}}{{R}_{MN 2}} = \frac{{K}_{MN 2}}{{K}_{MN 1}} = \frac{( {L}_{MN 1} \times {W}_{MN 2} )}{( {L}_{MN 2} \times {W}_{MN 1} )} \qquad ( 8 )$$

where L_{MN2} is the channel length of the second transistor MN2, and W_{MN2} is the channel width of the second transistor MN2.

Accordingly, using the same channel length and channel width for both the first transistor MN1 and the second transistor MN2 sets the drain-to-source resistance R_{MN2} of the second transistor MN2 equal to the drain-to-source resistance R_{MN1} of the first transistor MN1. Alternatively, the channel length and channel width of the first transistor MN1 may be different than the channel length and channel width of the second transistor MN2 such that the drain-to-source resistance R_{MN1} of the first transistor MN1 is proportional to the drain-to-source resistance R_{MN2} of the second transistor MN2.

As an example, in some exemplary embodiments of the analog multiplier the drain-to source resistance R_{MN2} of the second transistor MN2 may be a factor “n” times the drain-to-source resistance R_{MN1} of the first transistor MN1. In other embodiments, the resistance of the second resistor R₂ is also the factor “n” times the resistance of the first resistor R₁ such that the combined resistance of the drain-to-source resistance R_{MN2} of the second transistor and the resistance of the second resistor R₂ is the factor of “n” times the combined resistance of the of the drain-to-source resistance R_{MN1} of the first transistor and the resistance of the first resistor. In some embodiments the factor “n” is greater than one. In other embodiments the factor “n” may be less than one.

A constant current source I_{CC} is coupled between the first resistor R₁ and a supply voltage V_{SUPPLY}. The voltage generated across the first controlled resistance R_{REF}, (V_{REF}), is controlled based upon the first input voltage V₁ divided by the current passing through the constant current source I_{CC}, where the voltage drop across the inverting input of the first operational amplifier OPAMP₁ and the non-inverting input of the first operational amplifier OPAMP₁ is assumed to approach zero volts.

Accordingly, the resistance of the first controlled resistance R_{REF} is given by equation (9), where V₁ is a first control voltage.

$${R}_{REF} = \frac{{V}_{REF}}{{I}_{CC}} = \frac{{V}_{1}}{{I}_{CC}} \qquad ( 9 )$$

The analog multiplier 10 further includes a second operational amplifier OPAMP₂ having an inverting input coupled to a second control voltage V₂, and a non-inverting input coupled to the second controlled resistance R_{RP}. A drain of a third transistor MP1 is also coupled to the non-inverting input of the second operational amplifier OPAMP₂. The source of the third transistor MP1 is coupled to the supply voltage V_{SUPPLY}. The gate of the third transistor MP1 is coupled to the output of the second operational amplifier OPAMP₂.

A second input voltage V₂ is provided to the inverting input of the second operational amplifier OPAMP₂. Assuming that the voltage drop across the inverting input of the second operational amplifier OPAMP₂ and the non-inverting input of the second operational OPAMP₂ approaches zero volts, the second input voltage V₂ is placed across the second controlled resistance R_{RP}. Assuming that the current passing through the sixth resistor R₆ is more than an order of magnitude less than the drain current of the second transistor I_{MN2}, the current passing through the second controlled resistance R_{RP} (I_{MN2}) is given by equation (10).

$${I}_{MN 2} ≅ \frac{{V}_{2}}{{R}_{MN 2} + {R}_{2}} \qquad ( 10 )$$

Setting the resistance of the first resistor R₁ equal to the resistance of the second resistor R₂ such that R_{REF} equals R_{RP} yields equation (11), where R_{MN1} equals R_{MN2}.

$${I}_{MN 2} = [ \frac{{V}_{2}}{{V}_{1}} ] \times {I}_{CC} \qquad ( 11 )$$

Assuming that the input impedance of the second operational amplifier OPAMP₂ is very large, the drain current I_{MP1} of the third transistor MP1 equals the drain current I_{MN1} of the second transistor MN2. A fourth transistor MP2 mirrors the drain current I_{MP1} of the third transistor MP1. The fourth transistor MP2 includes a source coupled to the voltage supply V_{SUPPLY} and a gate coupled to the output of the second operational amplifier OPAMP₂. As a result, the output current I_{OUT} passing through the fourth transistor MP2 is equal to the drain current I_{MP1} passing through the third transistor MP1. In some embodiments of the analog multiplier 10 the fourth transistor MP2 may be configured to have an output current I_{OUT} proportional to the drain current passing through the third transistor MP1. Accordingly, the output current I_{OUT} is given by equation (12).

$${I}_{OUT} = [ \frac{{V}_{2}}{{V}_{1}} ] \times {I}_{CC} \qquad ( 12 )$$

In an alternative embodiment, the resistance of the first resistor and the second resistor are set to zero. In this case, the output current I_{OUT} may be based upon the ratio of the drain-to-source resistance R_{MN1} of the first transistor MN1 to the drain-to-source resistance R_{MN2} of the second transistor MN2, as shown in equation (13).

$${I}_{MN 2} = [ \frac{{V}_{2}}{{R}_{MN 2}} ] = [ \frac{{V}_{2}}{{V}_{1}} ] \times \frac{( {L}_{MN 1} \times {W}_{MN 2} )}{( {L}_{MN 2} \times {W}_{MN 1} )} \times {I}_{CC} \qquad ( 13 )$$

Accordingly, the output current I_{OUT} is given by equation (14), which permits the output current to be scaled according to the relative channel length to channel width ratios of the first transistor MN1 and the second transistor MN2.

$${I}_{OUT} = [ \frac{{V}_{2}}{{V}_{1}} ] \times \frac{( {L}_{MN 1} \times {W}_{MN 2} )}{( {L}_{MN 2} \times {W}_{MN 1} )} \times {I}_{CC} \qquad ( 14 )$$

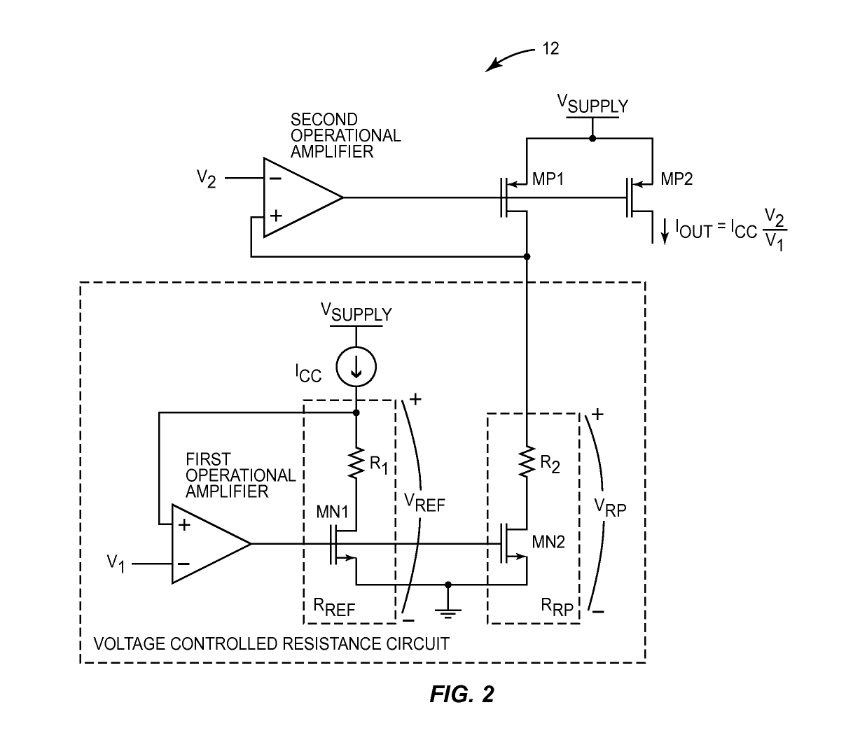

FIG. 2 depicts another exemplary embodiment of an analog multiplier 12, which is similar in function to the analog amplifier 10 depicted in FIG. 1. As depicted in FIG. 2, the first linearization circuit and the second linearization circuit are eliminated. The gates of the first transistor MN1 and the second transistor MN2 are directly tied to the output of the first operational amplifier. In addition, the fourth resistor R₄ and the sixth resistor R₆ are removed. Accordingly, the resistance of the first controlled resistance R_{REF} is given by equation (15).

$${R}_{REF} = \frac{1}{{K}_{MN 1} ( {V}_{{gs}_{MN 1}} - {V}_{t} - {V}_{{ds}_{MN 1}} / 2 )} + {R}_{1} \qquad ( 15 )$$

where V_{ds}_{_{MN1}} is the drain-to-source voltage across the first transistor MN1, and V_{gs}_{_{MN1}} is the gate-to-source voltage of the second transistor MN1.

Similarly, the resistance of the second controlled resistance R_{RP} is given by equation (16).

$${R}_{RP} = \frac{1}{{K}_{MN 2} ( {V}_{{gs}_{MN 2}} - {V}_{t} - {V}_{{ds}_{MN 2}} / 2 )} + {R}_{1} \qquad ( 16 )$$

where V_{ds}_{_{MN2}} is the drain-to-source voltage across the first transistor MN2, and V_{gs}_{_{MN2}} is the gate-to-source voltage of the second transistor MN2. The gate-to-source voltage V_{gs}_{_{MN1}} of the first transistor MN1 and the gate-to-source voltage V_{gs}_{_{MN2}} of the second transistor MN2 are each equal to V_{g}. When the first input voltage V₁ equals the second input voltage V₂, the drain-to-source resistance R_{MN1} of the first transistor MN1 equals the drain-to-source resistance R_{MN2} of the second transistor MN2. Otherwise, the drain-to-source resistance R_{MN1} of the first transistor MN1 does not equal the drain-to-source resistance R_{MN2} of the second transistor MN2 because V_{ds}_{_{MN1}}≠V_{ds}_{_{MN2}}. The difference between the drain-to-source resistance R_{MN1} of the first transistor MN1 and the drain-to-source resistance R_{MN2} of the second transistor MN2 may be calculated based upon the ratio of R_{MN1} divided by R_{MN2}, as shown in equation (17), where

$$[ \frac{{R}_{MN 1}}{{R}_{MN 2}} ] = 1 + \frac{K ( {V}_{{ds}_{MN 1}} - {V}_{{ds}_{MN 2}} )}{2 \times {I}_{CC}} {V}_{{DS}_{MN 1}} \qquad ( 17 )$$

where K_{MN1} and K_{MN2} are the same and

$${V}_{{gs}_{MN 1}} - {V}_{t} = {V}_{g} - {V}_{t} = \frac{{I}_{CC}}{K \times {V}_{{ds}_{MN 1}}} + {V}_{{ds}_{MN 1}} / 2 \qquad ( 17. b )$$

and which yields an error factor λ given as equation (17.c).

$$λ = \frac{K ( {V}_{{ds}_{MN 1}} - {V}_{{ds}_{MN 2}} )}{2 \times {I}_{CC}} {V}_{{DS}_{MN 1}} \qquad ( 17. c )$$

Accordingly, the error factor λ, by which R_{MN1} does not equal R_{MN2}, may be minimized by minimizing the difference between the V_{ds}_{_{MN1}} and V_{ds}_{_{MN2}} or increasing the current output of the constant current source I_{CC} relative to the value of K.

In an alternative exemplary embodiment, a first linearizing resistor (not shown) may be placed across the drain-to-source terminals of the first transistor MN1 and a second linearizing resistor (not shown) may be placed across the drain-to-source terminals of the second transistor MN2.

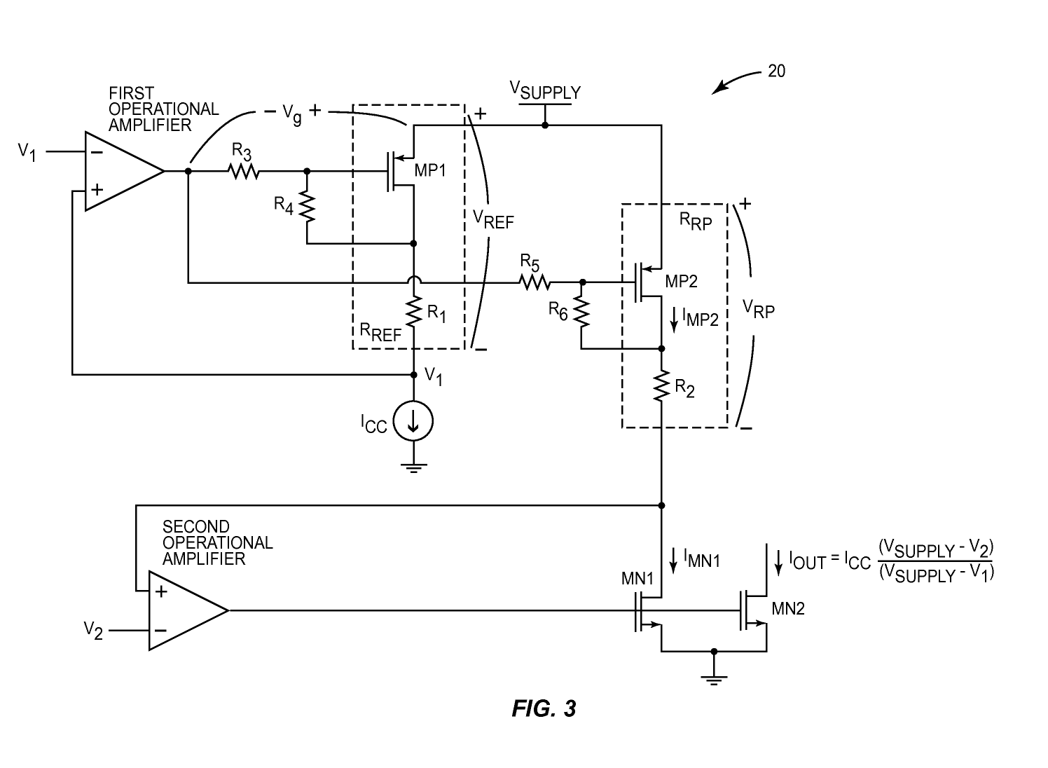

FIG. 3 depicts an exemplary embodiment of an analog multiplier 20 referenced to a constant current source I_{CC}. Similar to the analog multiplier 10 of FIG. 1, the analog multiplier 20 includes a first controlled resistance R_{REF} coupled between the supply voltage V_{SUPPLY} and the constant current source I_{CC}. The first controlled resistance R_{REF} includes the drain-to-source resistance R_{MP1} of the first transistor MP1 and resistance of the first resistor R₁. The analog multiplier 20 further includes a second controlled resistance R_{RP}, which includes the drain-to-source resistance R_{MP2} of the second transistor MP2 and the resistance of a second resistor R₂. The second controlled resistance R_{RP} is coupled between the voltage supply V_{SUPPLY} and the drain of a third transistor MN1. The source of the third transistor MN1 is coupled to a reference voltage, which may be ground. A fourth transistor MN2 is configured to mirror the drain current of the third transistor MN1. The source of the fourth transistor MN2 is coupled to the reference voltage, which may be ground.

Similar to analog multiplier 10 of FIG. 1, the analog multiplier 20 includes a first operational amplifier OPAMP₁ having an inverting input coupled to a first input voltage V₁, a non-inverting input coupled to the constant current source I_{CC}, and an output. The output of the first operational amplifier OPAMP₁ is coupled to a first linearization circuit formed by the third resistor R₃ and the fourth resistor R₄. The third resistor R₃ is coupled between the gate of the first transistor MP1 and the output of the first operational amplifier OPAMP₁. The fourth resistor R₄ is coupled between the gate and drain of the first transistor MP1. The output of the first operational amplifier OPAMP₁ is also coupled to a second linearization circuit formed by a fifth resistor R₅ and a sixth resistor R₆. The fifth resistor R₅ is coupled between the gate of the second transistor MP2 and the output of the first operational amplifier OPAMP₁. The sixth resistor R₆ is coupled between the gate and drain of the second transistor MP2.

Also similar to the analog multiplier 10 of FIG. 1, the drain-to-source resistance R_{MP1} of the first transistor MP1 is given by equation (18), and the drain-to-source resistance R_{MP2} of the second transistor MP2 is given by equation (19).

$$\begin{matrix}{R}_{MP 1} = \frac{1}{{K}_{MP 1} [ {V}_{g} / 2 - {V}_{t} ]} & ( 18 ) \\ {R}_{MP 2} = \frac{1}{{K}_{MP 2} [ {V}_{g} / 2 - {V}_{t} ]} & ( 19 )\end{matrix}$$

where V_{g} is the voltage between the output of the first operational amplifier OPAMP₁ and the sources of the first transistor MP1 and the second transistor MP2.

Also similar to the analog multiplier 10 of FIG. 1, the analog multiplier 20 of FIG. 3 further includes a second operational amplifier OPAMP₂ having an inverting output coupled to a second input voltage V₂, a non-inverting input coupled to the second resistor R₂, and an output coupled to the gate of the third transistor MN1.

The resistance of the first controlled resistance R_{REF} is given by equation (20), where V₁ is the first control voltage.

$${R}_{REF} = \frac{{V}_{REF}}{{I}_{CC}} = \frac{{V}_{SUPPLY} - {V}_{1}}{{I}_{CC}} \qquad ( 20 )$$

Assuming that the resistance of the first resistor R₁ equals the resistance of the second resistance R₂ and that K_{MP1}=K_{MP2}, the drain current of the second transistor MP2 is given by equation (21).

$${I}_{MP 2} = [ \frac{{V}_{SUPPLY} - {V}_{2}}{{V}_{SUPPLY} - {V}_{1}} ] \times {I}_{CC} \qquad ( 21 )$$

Assuming that the current passing through the sixth resistor R₆ is minimal compared to the drain current I_{MP2} of the second transistor MP2, the drain current I_{MN1} of the third transistor MN1 is substantially equal to the drain current I_{MP2} of the second transistor MP2. Because the fourth transistor MN2 is configured to mirror the drain current I_{MN1} of the third transistor MN1, the output current I_{OUT} is given by equation (22).

$${I}_{OUT} = [ \frac{{V}_{SUPPLY} - {V}_{2}}{{V}_{SUPPLY} - {V}_{1}} ] \times {I}_{CC} \qquad ( 22 )$$

Alternatively, a fifth transistor (not shown) may be configured to mirror the current through the second transistor MP2 of FIG. 3 by coupling the gate of the fifth transistor to the gate of the second transistor MP2. In this case, the source of the fifth transistor is coupled to the supply voltage V_{SUPPLY}. The drain current of the fifth transistor will be proportional to the drain current of the second transistor MP2 of FIG. 3.

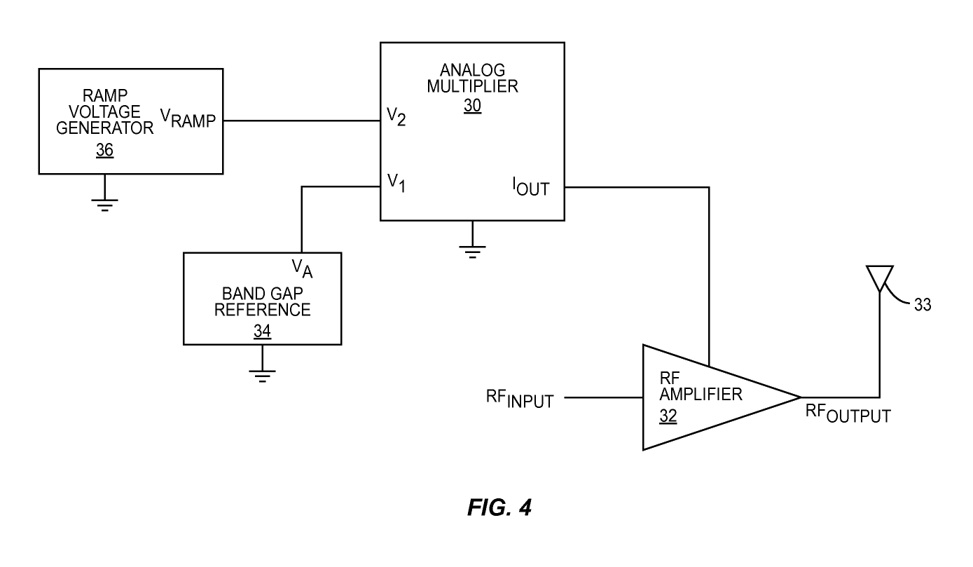

FIG. 4 depicts an exemplary application of the analog multiplier of FIG. 2 to control the operation of a radio frequency power amplifier. The analog multiplier 30 includes a first voltage input V₁, a second voltage input V₂, and a controlled current output I_{OUT}. Assuming that the analog multiplier 30 is similar to the analog amplifier 10 of FIG. 1, the output current I_{OUT} is given by equation (23),

$${I}_{OUT} = [ \frac{{V}_{2}}{{V}_{1}} ] \times {I}_{CC} \qquad ( 23 )$$

where I_{CC} is a reference current. The reference current I_{CC} may be set by an external resistance (not shown). The controlled current output I_{OUT} may be coupled to the power input of a radio frequency (RF) amplifier 32. The RF amplifier 32 may be configured to receive an RF input and provide an RF output to an antenna 33. The RF amplifier 32 may be a wideband code division multiple access (WCDMA) power amplifier.

A first reference voltage output V_{A} of a band gap reference 34 is coupled to the first voltage input V₁ of the analog multiplier 30. The band gap reference 34 may be configured to provide a substantially temperature invariant control voltage V_{A}. A ramp voltage generator circuit 36 includes a V_{RAMP} output voltage coupled to the second voltage input V₂ of the analog multiplier. The ramp voltage generator circuit 36 may include a configurable offset voltage. The V_{RAMP} output voltage may be used to control the output power of the RF amplifier 32.

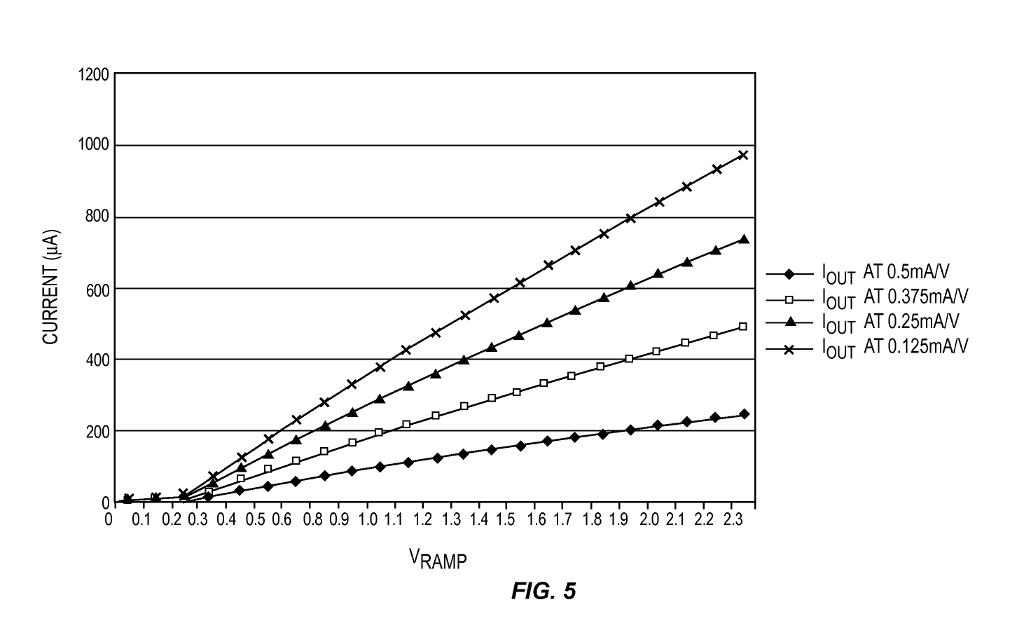

FIG. 5 depicts an example relationship between the controlled current output I_{OUT} of the analog multiplier 30 for different values of reference current I_{CC}, where the first voltage input V₁ is 2.0 volts, and the second voltage output V₂ equals (V_{RAMP}−0.2 volts), as shown in equation (24).

$${I}_{OUT} = [ \frac{{V}_{RAMP} - .2 V}{2 V} ] \times {I}_{CC} . \qquad ( 24 )$$

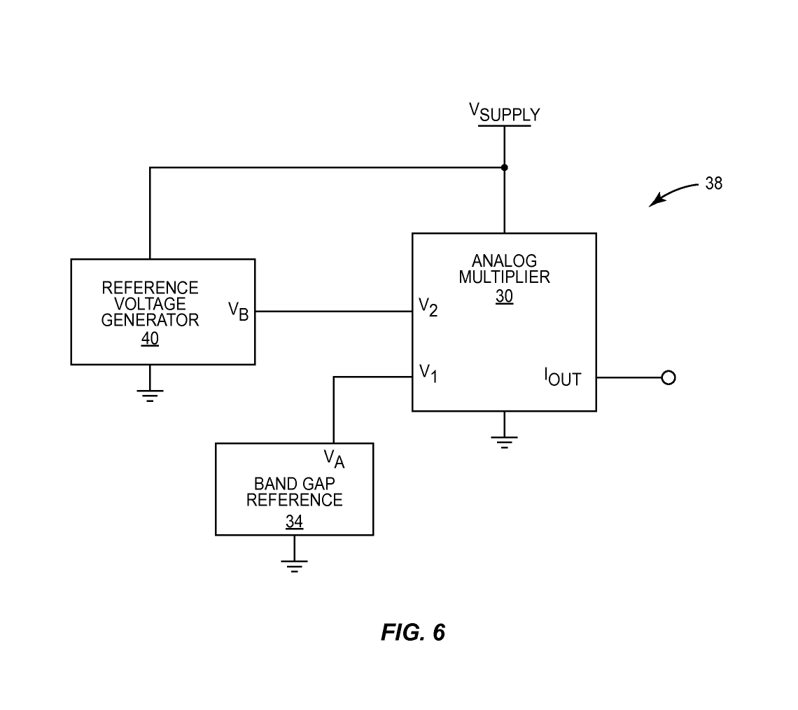

As depicted in FIG. 6, the non-linear error factor A for the analog multiplier 12 of FIG. 2 is less than 1%.

FIG. 6 depicts an exemplary application of the analog multiplier of FIGS. 1-2. A reference voltage generator circuit 40 includes an analog multiplier 32, a band gap reference 34, and a reference voltage generator 40. The first input voltage V₁ of the analog multiplier 32 may be coupled to the first reference voltage output V_{A} of the band gap reference 34. The second input voltage V₂ of the analog multiplier 32 may be coupled to a reference voltage generator output V_{B} of the reference voltage generator 40. The reference voltage generator output V_{B} may be a control voltage. As a non-limiting example, the reference voltage may be a proportional to absolute temperature voltage reference V_{PTAT}, an inversely proportional to absolute temperature voltage reference V_{NTAT}, or another band gap reference. The controlled current output I_{OUT} is controlled by the ratio of the V_{B} to V_{A}.

Those skilled in the art will recognize improvements and modifications to the embodiments of the present disclosure. All such improvements and modifications are considered within the scope of the concepts disclosed herein and the claims that follow.

What is claimed is:

1. An analog multiplier comprising:
a voltage controlled resistance circuit including a first node, a second node coupled to a supply voltage, a control node coupled to a first input voltage, and a reference current source configured to provide a reference current, wherein a resistance between the first node and the second node of the voltage controlled resistance circuit is based upon a ratio of the supply voltage less the first input voltage divided by the reference current;
a first operational amplifier including an inverted input coupled to a second input voltage, a non-inverted input coupled to the first node of the voltage controlled resistance circuit, and an output node; and
a first transistor including a gate in communication with the output node of the first operational amplifier, a source coupled to a reference voltage, and a drain coupled to the non-inverted input of the first operational amplifier and the first node of the voltage controlled resistance circuit.

2. The analog multiplier of claim 1 further comprising:
a second transistor configured to mirror a drain current of the first transistor, wherein a drain current of the second transistor is substantially proportional to the drain current of the first transistor.

3. The analog multiplier of claim 2 wherein the reference current source of the voltage controlled resistance circuit includes a first node coupled to the reference voltage and a second node, the voltage controlled resistance circuit further comprises:
a third transistor including a source coupled to the second node of the voltage controlled resistance circuit, a drain, and a gate;
a first resistor including a first terminal coupled to the second node of the reference current source and a second terminal coupled to the drain of the third transistor;
a second operational amplifier including an inverted input coupled to the control node of the voltage controlled resistance circuit, a non-inverted input coupled to the second node of the reference current source, and an output in communication with the gate of the third transistor;
a fourth transistor including a gate in communication with the output of the second operational amplifier, a source coupled to the reference voltage, and a drain; and
a second resistor including a first terminal coupled to the drain of the fourth transistor and a second terminal coupled to the first node of the voltage controlled resistance circuit.

4. The analog multiplier of claim 3 wherein a resistance of the first resistor substantially equals a resistance of the second resistor.

5. The analog multiplier of claim 4 wherein a third resistor is coupled between the output of the second operational amplifier and the gate of the third transistor, and a fourth resistor is coupled between the gate of the third transistor and the drain of the third transistor; and
wherein a fifth resistor is coupled between the output of the second operational amplifier and a gate of the fourth transistor, and a sixth resistor is coupled between the gate of the fourth transistor and the drain of the fourth transistor.

6. The analog multiplier of claim 5 wherein a resistance of the third resistor substantially equals a resistance of the fourth resistor; and
wherein a resistance of the fifth resistor substantially equals a resistance of the sixth resistor.

7. The analog multiplier of claim 6 wherein the resistance of the fifth resistor substantially equals the resistance of the third resistor.

8. The analog multiplier of claim 7 further comprising a band gap voltage reference configured to provide the first input voltage to the voltage controlled resistance circuit.

9. The analog multiplier of claim 8 further comprising a ramp voltage generator configured to provide the second input voltage to the first operational amplifier to control a radio frequency power amplifier.

10. The analog multiplier of claim 9 further comprising coupling the drain of the second transistor to a power input of the radio frequency power amplifier.

11. The analog multiplier of claim 8 further comprising a proportional to absolute temperature voltage source configured to provide the second input voltage to the first operational amplifier.

12. The analog multiplier of claim 8 further comprising an inversely proportional to absolute temperature voltage source configured to provide the second input voltage to the first operational amplifier.

13. The analog multiplier of claim 2 further comprising a band gap voltage reference configured to provide the first input voltage to the voltage controlled resistance circuit.

14. The analog multiplier of claim 13 further comprising a ramp voltage generator configured to provide the second input voltage to the first operational amplifier.

15. The analog multiplier of claim 14 wherein the drain of the second transistor is in communication with a power control input of a wideband code division multiple access radio frequency power amplifier.

16. The analog multiplier of claim 13 further comprising a proportional to absolute temperature voltage source configured to provide the second input voltage to the first operational amplifier.

17. The analog multiplier of claim 13 further comprising an inversely proportional to absolute temperature voltage source configured to provide the second input voltage to the first operational amplifier.

18. The analog multiplier of claim 1 wherein the reference current source of the voltage controlled resistance circuit includes a first node coupled to the reference voltage and a second node, and wherein the voltage controlled resistance circuit further comprises:
a third transistor including a source in communication with the second node of the voltage controlled resistance circuit, a drain in communication with the second node of the reference current source, and a gate;
a second operational amplifier including an inverted input coupled to the control node of the voltage controlled resistance circuit, a non-inverted input coupled to the second node of the reference current source, and an output in communication with the gate of the third transistor; and
a fourth transistor including a gate in communication with the output of the second operational amplifier, a source coupled to the second node of the voltage controlled resistance circuit, and a drain in communication with the first node of the voltage controlled resistance circuit.

19. The analog multiplier of claim 18 further comprising a first resistor coupled between the gate of the third transistor and the drain of the third transistor; and
a second resistor coupled between the gate of the third transistor and the output of the second operational amplifier;
a third resistor coupled between the gate of the fourth transistor and the drain of the fourth transistor; and
a fourth resistor coupled between the gate of the fourth transistor and the output of the second operational amplifier.

20. The analog multiplier of claim 19 wherein:
a resistance of the first resistor is substantially equal to a resistance of the second resistor; and
a resistance of the third resistor is substantially equal to a resistance of the fourth resistor.

21. The analog multiplier of claim 20 further comprising a fifth resistor coupled between the drain of the third transistor and the second node of the reference current source; and
a sixth resistor coupled between the drain of the fourth transistor and the first node of the voltage controlled resistance circuit.

22. The analog multiplier of claim 21 wherein a resistance of the fifth resistor is substantially equal to a resistance of the sixth resistor.

23. The analog multiplier of claim 21 further comprising a fifth transistor including a gate coupled to the gate of the fourth transistor, wherein a drain current of the fifth transistor is proportional to a drain current of the fourth transistor.

24. The analog multiplier of claim 23 wherein a drain of the fifth transistor is in communication with a power control input of a wideband code division multiple access (WCDMA) radio frequency power amplifier.

25. The analog multiplier of claim 18 further including a first resistor coupled between the drain and source of the third transistor; and
a second resistor coupled between the drain and the source of the fourth transistor.

26. The analog multiplier of claim 1 wherein the resistance between the first node and second node of the voltage controlled resistance circuit is substantially proportional to the first input voltage divided by the reference current.

27. The analog multiplier of claim 1 wherein the resistance between the first node and the second node of the voltage controlled resistance circuit is quasi-equal to the first input voltage divided by the reference current.

28. A method to provide an analog multiplier comprising:
generating a reference current, wherein the reference current passes through a first element;
controlling a first voltage generated across the first element to set a resistance of the first element based upon a first input voltage;
controlling a resistance of a second element to be substantially proportional to the resistance of the first element; and
controlling a second voltage generated across the second element to generate a current passing through a third element based upon a second input voltage.

29. The method of claim 28 further comprising:
mirroring the current passing through the one of the second element and the third element to generate an output current proportional to the reference current multiplied by a ratio of the second voltage divided by the first voltage.

30. The method of claim 28 further comprising:
mirroring the current passing through the third element to generate an output current proportional to the reference current multiplied by a ratio of the second voltage divided by the first voltage.

31. The method of claim 28 wherein controlling the first voltage generated across the first element to set the resistance of the first element comprises:
receiving the first input voltage at an operational amplifier;
controlling, with the operational amplifier, the first voltage generated across the first element based upon the first input voltage.

32. The method of claim 31 further comprising:
generating the first input voltage based upon a band gap reference voltage.

33. The method of claim 32 wherein the operational amplifier is a first operational amplifier, and wherein controlling the second voltage generated across the second element to generate the current passing through a third element further comprises:
receiving the second input voltage at a second operational amplifier, wherein the second operational amplifier is configured to control the second voltage generated across the second element;
generating the second input voltage based upon a voltage ramp signal used to control a radio frequency power amplifier;
generating an output current through a fourth element based upon the current passing through the third element; and
providing the output current from the fourth element to the radio frequency power amplifier.

34. The method of claim 32 wherein the operational amplifier is a first operational amplifier, wherein controlling a second voltage generated across the second element to generate a current passing through a third element further comprises:
receiving a second input voltage at a second operational amplifier, wherein the operational amplifier is configured to control the second voltage generated across the second element; and
wherein the second input voltage is one of a proportional to absolute temperature voltage source and an inversely proportional to absolute temperature voltage source.

35. The method of claim 28 wherein the resistance of the first element includes a drain-to-source resistance of a first transistors and a resistance of a first resistor; and
wherein the resistance of the second element includes a drain-to-source resistance of a second transistor and a resistance of a second resistor.

36. The method of claim 35 wherein the resistance of the first element is substantially equal to the resistance of the second element.

37. The method of claim 28 wherein the resistance of the first element includes a drain-to-source resistance of a first transistor; and
wherein the resistance of the second element includes a drain-to-source resistance of a second transistor.

38. The method of claim 37 wherein a ratio of a channel length to a channel width of the second transistor is proportional to a ratio of a channel length to a channel width of the first transistor.

39. The method of claim 38 wherein the ratio of the channel length to the channel width of the second transistor is smaller than the ratio of the channel length to channel width of the second transistor by a factor n.

40. The method of claim 39 wherein the resistance of the first element further includes a resistance of a first resistor;
wherein the resistance of the second element further includes a resistance of a second resistor, and
wherein the resistance of the second resistor is substantially equal to n times the resistance of the resistance of the first resistor.

41. The method of claim 37 wherein the resistance of the first element includes a drain-to-source resistance of a first transistor configured to operate in a triode mode;
wherein the resistance of the second element includes a drain-to-source resistance of a second transistor configured to operate in a triode mode; and
wherein a ratio of a channel length to a channel width of the second transistor is proportional to a ratio of a channel length to a channel width of the first transistor.

42. The method of claim 28 wherein the resistance of the second element is substantially equal to the resistance of the first element.

43. The method of claim 28 wherein the resistance of the first element includes a drain-to-source resistance of a first transistor configured to operate in a triode mode;
wherein the resistance of the second element includes a drain-to-source resistance of a second transistor configured to operate in a triode mode; and
wherein a ratio of a channel length to a channel width of the second transistor is substantially equal to a ratio of a channel length to a channel width of the first transistor.

44. The analog multiplier of claim 18 wherein the third transistor is configured to operate in a triode mode;
wherein the fourth transistor is configured to operate in the triode mode; and
wherein a drain-to-source resistance of the fourth transistor is proportional to the drain-to-source resistance of the third transistor.

45. The analog multiplier of claim 18 wherein a ratio of a channel length to a channel width of the fourth transistor is proportional to a ratio of a channel length to a channel width of the third transistor.

46. The analog multiplier of claim 45 wherein the ratio of the channel length to the channel width of the fourth transistor is smaller than the ratio of the channel length to channel width of the third transistor by a factor n.

47. The analog multiplier of claim 46 further including a third resistor coupled between the drain of the third transistor and the reference current source and a fourth resistor coupled between the drain of the fourth transistor and the first node of the voltage controlled resistance circuit, and
wherein a resistance of the fourth transistor is smaller than a resistance of the third transistor by a factor of n.

48. The analog multiplier of claim 45 wherein the ratio of the channel length to the channel width of the fourth transistor is larger than the ratio of the channel length to channel width of the third transistor by a factor n.

49. The analog multiplier of claim 48 further including a third resistor coupled between the drain of the third transistor and the reference current source and a fourth resistor coupled between the drain of the fourth transistor and the first node of the voltage controlled resistance circuit, and
wherein a resistance of the fourth transistor is larger than a resistance of the third transistor by a factor of n.
